(19) United States
(12) Patent Application Publication
(10) Pub. No.: US 2007/0290185 A1
(43) Pub. Date: Dec. 20, 2007

(54) Phase change memory cells and methods for fabricating the same

(75) Inventor: Wen-Han Wang, Hsinchu City (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/525,286

(22) Filed: Sep. 22, 2006

(30) Foreign Application Priority Data
Jun. 15, 2006 (TW) TW95121385

(51) Int. Cl. H01L 29/04

(52) U.S. Cl. 257/3

(57) ABSTRACT

Phase change memory cells and methods for fabricating the same are provided. In an exemplary embodiment, a phase change memory cell comprises a first electrode disposed over a substrate along a first direction. A first dielectric layer is formed over the first electrode. A conductive contact is formed in the first dielectric layer, electrically contacting the first electrode, wherein the conductive contact has an L-shaped or reverse L-shaped ( [symbol] ) cross section. A second dielectric layer is formed over the first dielectric layer. A phase change layer is partially formed over the first and the second dielectric layers, electrically contacting the conductive contact. A third dielectric layer is formed over the phase change layer and the first and second dielectric layers with an opening therein. A second electrode layer is formed over the third dielectric layer and fills the opening to electrically contact the phase change layer.

### BACKGROUND OF THE INVENTION

1. Field of the Invention

The invention relates to a memory device and in particular to a phase change memory cell and a method for fabricating the same.

2. Description of the Related Art

Phase change memory devices are non-volatile, highly readable, highly programmable, and require a lower driving voltage/current. Modern topics of the phase change memory device are to increase cell density and reduce current density thereof.

Phase change material in a phase change memory device has at least two solid phases, a crystalline state and an amorphous state. Transformation between these two phases can be achieved by inputting two different electrical pulses into the phase change material. The phase change material exhibits different electrical characteristics depending on its state. For example, in its amorphous state the material exhibits a higher resistivity than it is in the crystalline state. Such phase change material may switch between numerous electrically detectable conditions of varying resistivity on a nanosecond time scale with the input of pico joules of energy. Chalcogenide material is a popular and wildly used phase change material in modern phase change memory technology.

Since phase change material allows a reversible phase transformation, memory status can be distinguished by telling whether a memory bit is in high resistance state or in low resistance state.

U.S. Pat. No. 6,534,780 discloses a memory cell structure utilizing a phase change material, wherein the memory cell is formed at four individual corners of a crisscross protrusion. Fabrication of such memory cell structure may utilize about 10 photolithography processes. Thus, performance of the memory units in the formed memory cell structure is easily affected and individual unit quality may vary.

### SUMMARY

Phase change memory cells and methods for fabricating the same are provided. An exemplary embodiment, a phase change memory cell comprises a first electrode disposed over a substrate along a first direction. A first dielectric layer is formed over the first electrode. A conductive contact is formed in the first dielectric layer, electrically contacting the first electrode, wherein the conductive contact has an L-shaped or reverse L-shaped ( [symbol] ) cross section. A second dielectric layer is formed over the first dielectric layer, covering the conductive contact. A phase change layer is partially formed over the first and the second dielectric layers, electrically contacting the conductive contact. A third dielectric layer is formed over the phase change layer and the first and second dielectric layers, having an opening exposing a portion of the phase change layer. A second electrode layer is formed over the third dielectric layer, filling the opening and electrically contacting the phase change layer.

In another exemplary embodiment, a phase change memory cell comprises a first electrode disposed over a substrate along a first direction. A first dielectric layer is formed to cover the first electrode and the substrate. A pair of conductive contacts is respectively formed in different portions of the first dielectric layer to electrically contact the first electrode, wherein the conductive contacts have an L-shaped or reverse L-shaped ( [symbol] ) cross section. A second dielectric layer is formed over the first dielectric layer, covering the conductive contacts. A phase change layer is partially formed over the first and the second dielectric layers, electrically contacting one of the conductive contacts. A third dielectric layer is formed over the phase change layer and the first and second dielectric layers, having an opening exposing a portion of the phase change layer. A second electrode is formed over the third dielectric layer along a second direction and filling the opening, electrically contacting the phase change layer.

Another exemplary embodiment of a method for fabricating a phase change memory cell comprises forming a first electrode over a substrate, wherein the first electrode extends along a first direction and partially covers the substrate. A first dielectric layer is formed over the substrate, covering the first electrode and the substrate. A first opening is formed in the first dielectric layer, exposing a portion of the first electrode. A pair of conductive contacts of L-shaped or reverse L-shaped ( [symbol] ) cross sections are respectively formed on both sides of the first opening, the conductive contacts contact the first electrode and a sidewall of the first dielectric layer exposed by the first opening, respectively. The first opening is filled with a second dielectric layer, wherein the second dielectric layer covers the conductive contacts. A pair of phase change layers are formed, each of the phase change layers partially overlies the first and second dielectric layers and electrically contact the conductive contact. A third dielectric layer is formed over the phase change layers and the first and second dielectric layers. A pair of second openings is formed in the third dielectric layer, respectively exposing a portion of each of the phase change layers. A second electrode is formed over the third dielectric layer, extending along a second direction and filling the second openings, respectively electrically contacting the phase change layers, wherein the second direction is different to that of the first direction.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1A, 2A, 3A, 4A and 5A are schematic top views illustrating fabrications during a phase change memory device according to an embodiment of the invention;

FIG. 1B is a schematic view illustrating a cross section taken along line 1B-1B in FIG. 1A;

FIG. 2B is a schematic view illustrating a cross section taken along line 2B-2B in FIG. 2A;

FIG. 3B is a schematic view illustrating a cross section taken along line 3B-3B in FIG. 3A;

FIG. 4B is a schematic view illustrating a cross section taken along line 4B-4B in FIG. 4A;

FIG. 5B is a schematic view illustrating a cross section taken along line 5B-5B in FIG. 5A;

FIGS. 6A and 7A are schematic top views illustrating fabrication of a phase change memory device according to another embodiment of the invention;

FIG. 6B is a schematic view illustrating a cross section taken along line 6B-6B in FIG. 6A; and

FIG. 7B is a schematic view illustrating a cross section taken along line 7B-7B in FIG. 7A.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

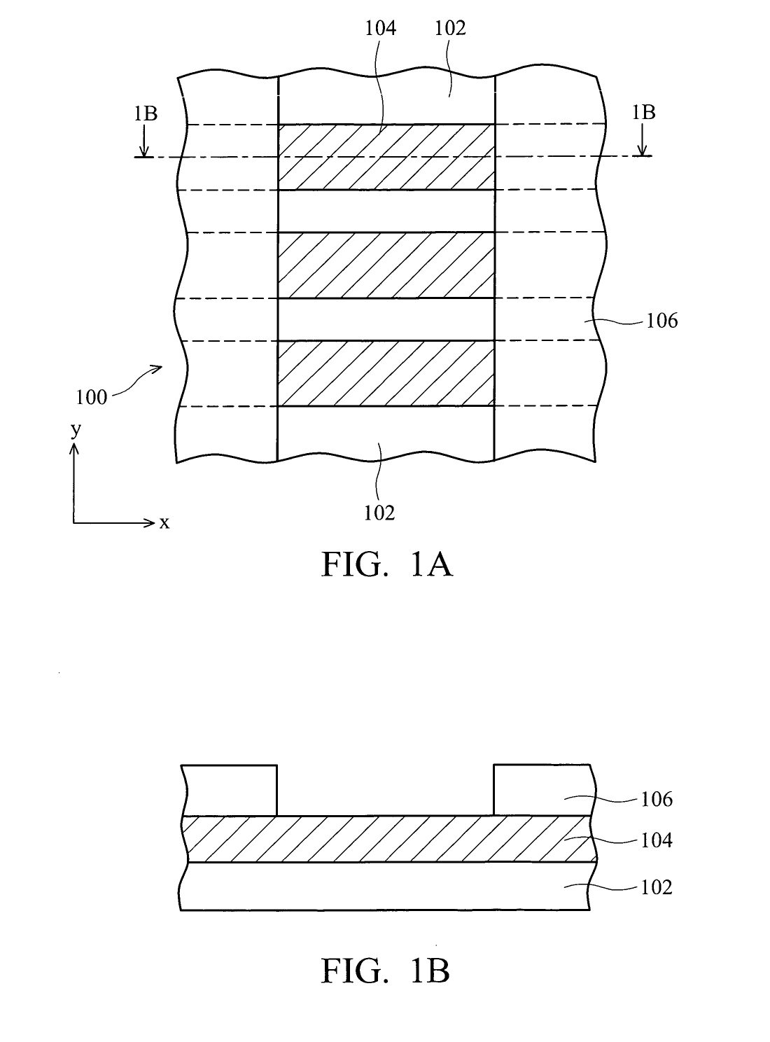

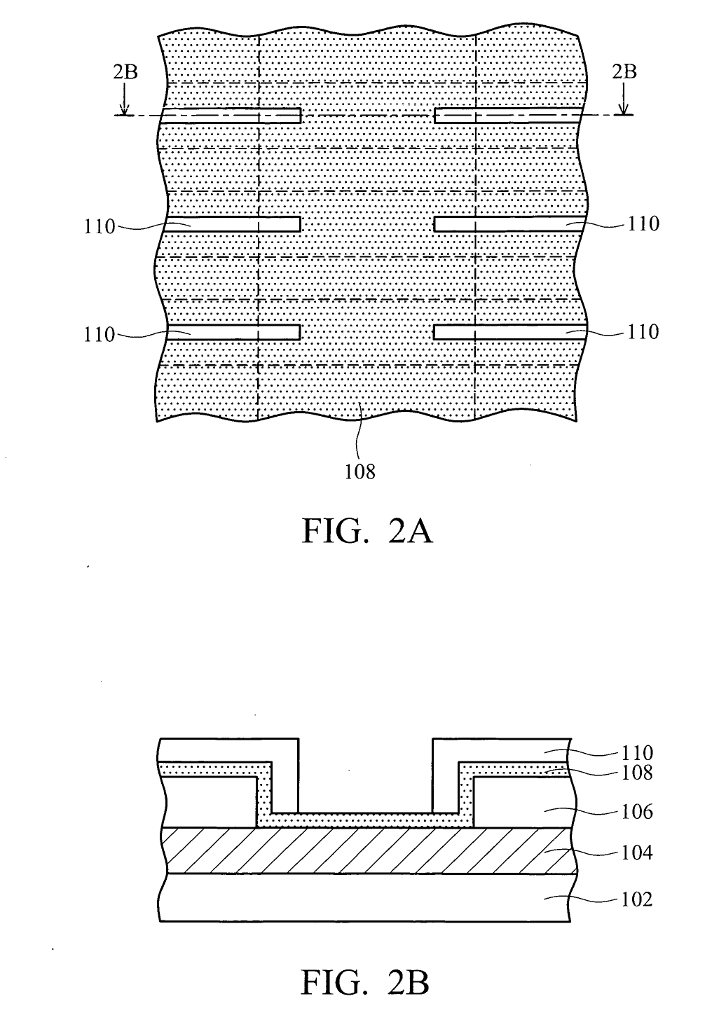

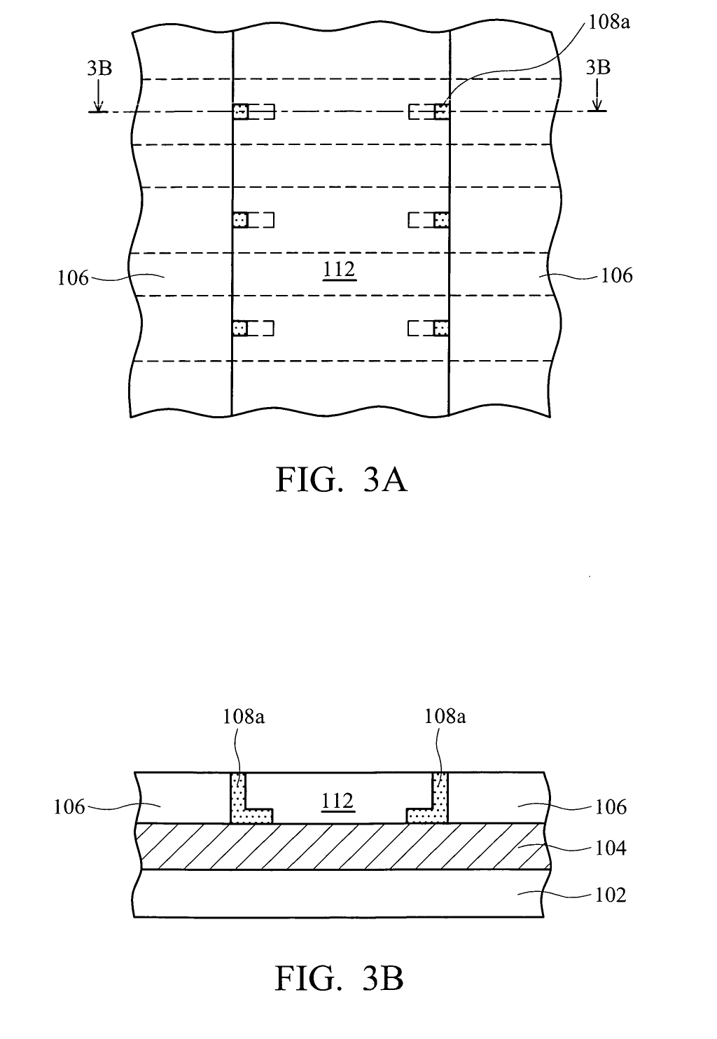

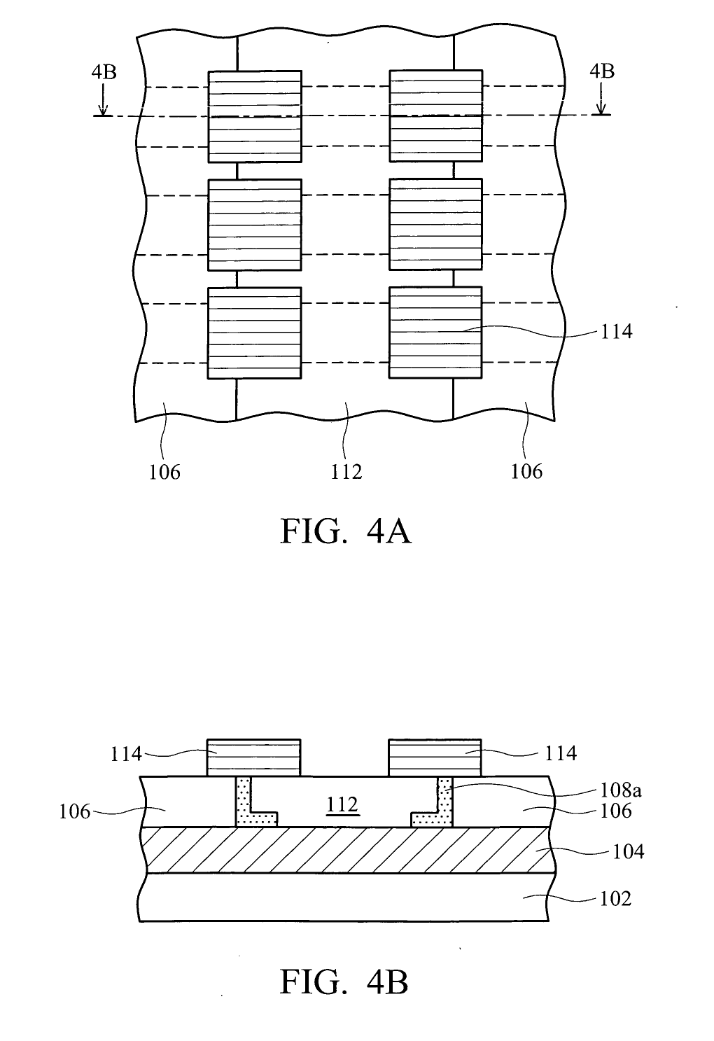

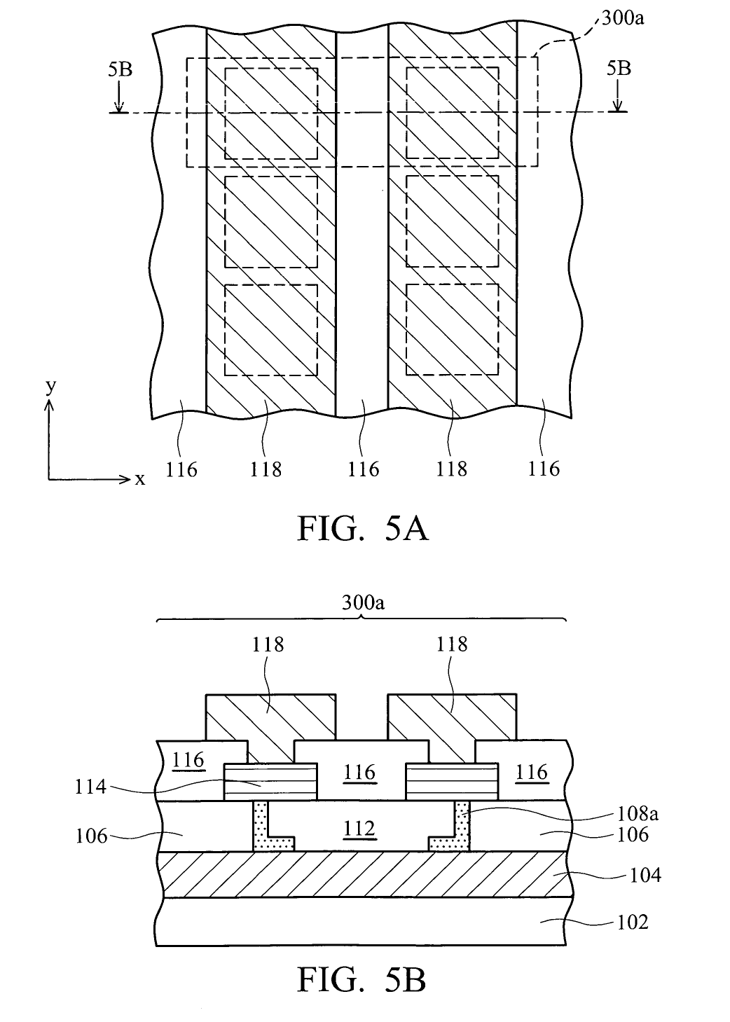

FIGS. 1A-1B, 2A-2B, 3A-3B, 4A-4B and 5A-5B are schematic views illustrating the fabrications of a phase change memory device during different stages according to an embodiment of the invention, wherein FIGS. 1A, 2A, 3A, 4A and 5A are schematic top views and FIGS. 1B, 2B, 3B, 4B and 5B are schematic cross sections taken along lines 1B-1B in FIG. 1A, 2B-2B in FIG. 2A, 3B-3B in FIG. 3A, 4B-4B in FIGS. 4A and 5B-5B in FIG. 5A, respectively.

Referring now to FIGS. 1A and 1B, a part of a memory cell array of a phase change memory device 100 is illustrated. The phase change memory device 100 is partially fabricated and includes a semiconductor substrate, for example a silicon substrate. The semiconductor substrate can be formed with a semiconductor device and/or other conductive interconnect structures. The semiconductor devices can be, for example, active devices and electrically contact the memory cells in the memory cell array through the conductive interconnect structures to thereby control the memory status thereof. For simplicity, the semiconductor substrate is illustrated as a substrate 102 with a planar surface, as shown in FIG. 1B.

Next, a layer of conductive material such as Ti, TiN, TiW, W, Al, Cu or TaN is formed over the substrate 102 by methods such as chemical vapor deposition (CVD) or sputtering. A photolithography process (not shown) is then performed to pattern the layer of conductive material, such that a plurality of isolated conductive layer 104 is formed over the substrate 102. As shown in FIG. 1A, the conductive layers 104 are arranged in parallel, each extending along an x direction in FIG. 1A and partially covering a portion of the substrate 102. A layer of dielectric material such as boronphophosilicate glass (BPSG), silicon oxide or silicon nitride is then formed over the substrate 102 with a thickness greater than that of the conductive layers 104. A photolithography process (not shown) is then performed to pattern the layer of dielectric material, forming a patterned dielectric layer 106 with an opening therein, exposing portions of the conductive layer 104 and the substrate 102 therein, as shown in FIG. 1A.

Referring now to FIGS. 2A and 2B, a conductive layer 108 is next formed over the structure illustrated in FIGS. 1A and 1B. The conductive layer 108 conformably covers the dielectric layer 106, and sidewalls of the dielectric layer 106 and the conductive layer 104 exposed by the opening. The conductive layer 108 may comprise TiN, TaN, TiW or TiAlN, and is formed with a thickness of about 1-100 nm, preferably of about 5 nm. The conductive layer 108 can be formed by, for example, CVD or sputtering. A layer of photoresist material is next formed over the substrate 102 and blanketly covers the conductive layer 108, thereby providing a planar surface. A photolithography process (not shown) is then performed to pattern the layer of the photoresist material, thereby forming a plurality of patterned photoresist layer 110 illustrated in FIG. 2A. Each of the patterned photoresist layers 110 respectively covers portions of the underlying conductive layer 108 and is substantially located over an underlying conductive layer 104. FIG. 2B illustrates a cross section taken along line 2B-2B in FIG. 2A, the photoresist layer 110 is now formed on both sides of the conductive layer 104 and substantially covers the conductive layer 108 overlying the dielectric layer 106. The photoresist layer 110 also formed in the opening defined by the dielectric layer 106 and thereby forms a smaller opening partially exposing the conductive layer 108 therein.

Referring now to FIGS. 3A and 3B, an etching (not shown) is next performed on the structure illustrated in FIGS. 2A and 2B, using the photoresist layer 110 as a mask, to remove the conductive layer 108 not covered by the photoresist layer 110. Next, after removal of the photoresist layer 110, a layer of dielectric material is blanketly formed, covering the dielectric layer 106 and filling in the opening defined in the dielectric layer 106. The layer of dielectric material may comprise BPSG, silicon oxide or spin on glass (SOG) formed by methods such as CVD or spin coating. Next, a planarization process, such as chemical mechanical polishing (CMP), is performed to remove portions of the dielectric material and the conductive layer 108 over the top surface of the dielectric layer 106, thereby forming a dielectric layer 112 in the opening formed in the dielectric layer 106. As shown in FIG. 3B, which is a cross section taken along line 3B-3B in FIG. 3A, a pair of conductive contact 108a are respectively formed on both sides of the opening defined in the dielectric layer 106. The conductive contacts 108a are electrically isolated from each other, having an L-shaped or reverse L-shaped ( [symbol] ) cross section. Each of the conductive contacts 108a includes a vertical portion contacting a sidewall of the dielectric layer 106 and a bottom portion contacting the conductive layer 104. As shown in FIG. 3B, the dielectric layer 106, the dielectric layer 112 and the conductive contacts 108a are substantially coplanar, thereby providing a planar surface preferable for subsequent processing.

Referring now to FIGS. 4A and 4B, a layer of phase change material is blanketly formed over the substrate 102, covering the dielectric layers 106, 112, and the conductive contacts 108a illustrated in FIGS. 3A and 3B. The phase change material may comprise chalcogenide materials such as Ge—Te—Sb trinary chalcogenide compound or Te—Sb binary chalcogenide compound and can be formed by methods such as CVD or sputtering. The layer of phase change material is formed at a thickness of about 20-100 nm, preferably about 100 nm. Next, a photolithography process (not shown) is performed to pattern the layer of the phase change material, thereby forming a plurality of patterned phase change layers 114 as shown in FIG. 4A. As shown in 4B, the phase change layers 114 are isolated from each other and cover one of the underlying conductive contacts 108a, respectively, to thereby electrically connect the underlying conductive layer 104.

Referring now to FIGS. 5A and 5B, a blanket dielectric layer 116 is next formed over the structure illustrated in FIGS. 4A and 4B. The dielectric layer 116 is formed with a thickness greater than that of the phase change layer 114. The dielectric layer 116 may comprise BPSG, silicon oxide, or SOG and can be formed by methods such as CVD or spin-coating. A photolithography process (not shown) is then performed on the dielectric layer to form a plurality of openings therein, each of the openings substantially aligns to an underlying phase change layer 114 and exposes a portion thereof. A layer of conductive material, for example Al, Ti, TiN, is then formed over the dielectric layer 116 and fills the openings defined in the dielectric layer 116. The layer of conductive material is next patterned by a photolithography process (not shown) to form a plurality of isolated conductive layers 118. As shown in FIG. 5A, the conductive layers 118 are now arranged in parallel along a y direction and partially cover the dielectric layer 116. As shown in FIG. 5B, each conductive layer 118 comprises a protrusion extending downward and filling the opening formed in the dielectric layer 116 over the phase change layer 114, thereby electrically contacting the underlying phase change layer 114.

Thus, fabrications of cells of a phase change memory device according to an embodiment of the invention are completed. As shown in FIG. 5A, the dotted area 300a illustrates an area of a memory cell unit and FIG. 5B illustrates a cross section thereof, including a first electrode (the conductive layer 104) disposed over a substrate (the substrate 102) along a first direction (the x direction in FIG. 5A). A first dielectric layer (the dielectric layer 106) is formed to cover the first electrode and the substrate. A pair of conductive contacts (the conductive contact 108a) is respectively formed in different portions of the first dielectric layer to electrically contact the first electrode, wherein the conductive contacts have an L-shaped or reverse L-shaped ( [symbol] ) cross section. A second dielectric layer (the dielectric layer 116) is formed over the first dielectric layer, covering the conductive contacts. A phase change layer (the phase change layer 114) is partially formed over the first and the second dielectric layers, electrically contacting one of the conductive contacts. A third dielectric layer is formed over the phase change layer and the first and second dielectric layers, having an opening exposing a portion of the phase change layer. A second electrode (the conductive layer 118) is formed over the third dielectric layer along a second direction and filling the opening, electrically contacting the phase change layer.

The memory cell unit illustrated in above embodiment is a dual-bit memory cell, the first electrode (the conductive layer 104) therein may electrically connect an active device (not shown) formed over the substrate 102 and provides four different memory statuses through the operation of the second electrode (the conductive layer 118). In addition, a more integrated phase memory device array can be achieved by repeatedly arranging the memory cell unit illustrated in FIGS. 5A and 5B and a simplified process adopting merely six photolithography steps. Therefore, a memory cell array with higher cell density and fewer performance variations is obtained, thereby reducing or even preventing the undesirable issues of U.S. Pat. No. 6,534,780. Moreover, the conductive contact of the L-shaped or reverse L-shaped ( [symbol] ) cross section in the memory cell functions as a conductive electrode formed between the underlying and overlying electrodes, having a reduced contact area therebetween. Thus, the volume occupied in the memory cell is reduced.

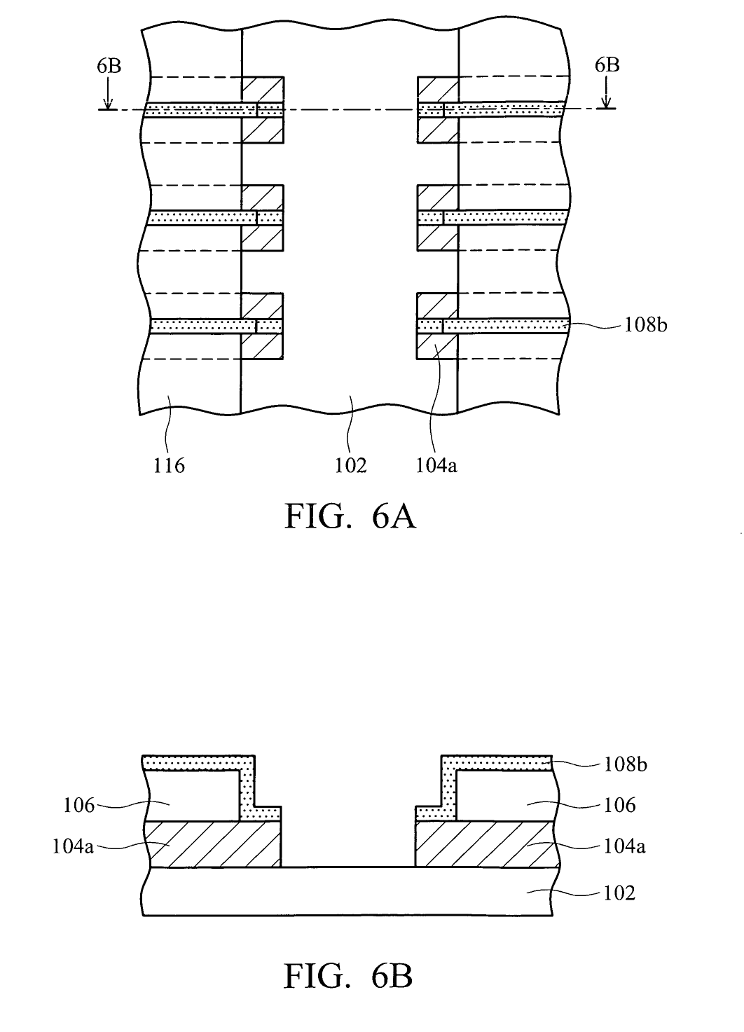

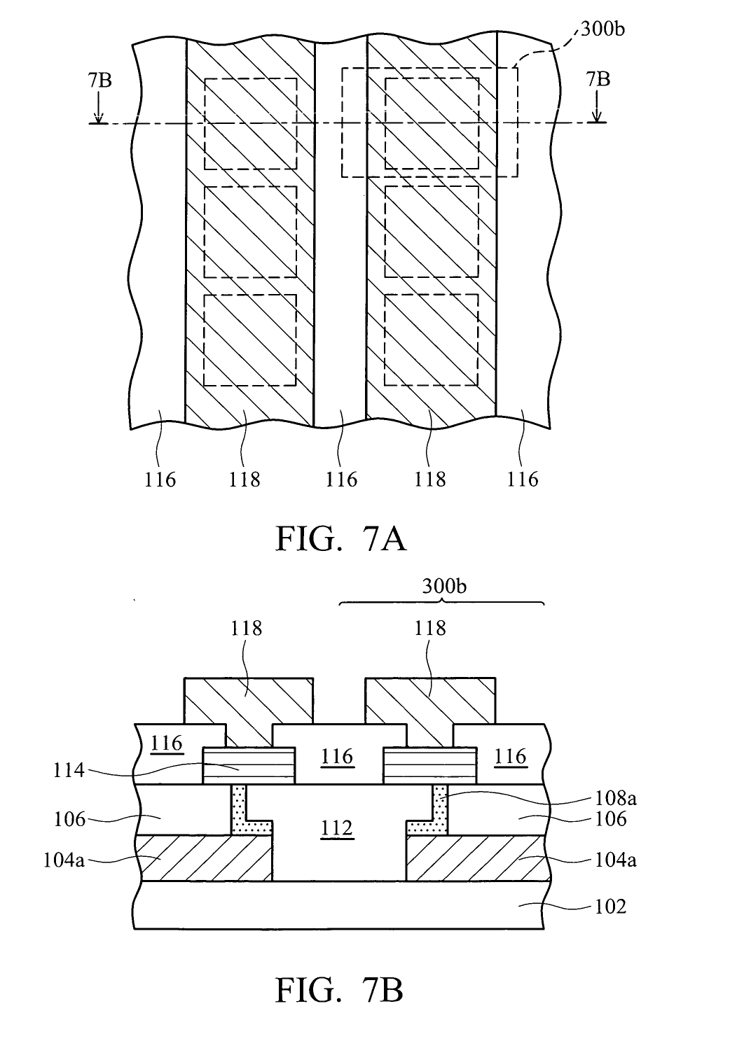

FIGS. 6A-6B and 7A-7B are schematic views illustrating fabrication of a phase change memory device according to a modified embodiment similar to the previous embodiment, wherein FIGS. 6A and 7A are schematic top views and FIGS. 6B and 7B are schematic cross sections taken along lines 6B-6B in FIGS. 6A and 7B-7B in FIG. 7A, respectively. Similar fabrications are not described here again but only differences therebetween are described as follow.

Referring now to FIGS. 6A and 6B, the structure illustrated in FIGS. 2A and 2B are first provided through fabrications illustrated in FIGS. 1A-1B and 2A-2B. Next, an etching (not shown) is performed on the structure illustrated in FIGS. 2A and 2B to remove the conductive layer 108 exposed by the photoresist layer 110, using the photoresist layer 110 as a mask, thereby leaving the patterned conductive layers 108. Next, after removal of the photoresist layer 110, another photoresist layer (not shown) is formed and patterned by another photolithography process (not shown), thereby forming an opening therein, having an edge substantially aligning to an edge of the conductive layer 108 in the opening defined in the dielectric layer 106 and exposing portions of the underlying conductive layer 104. An etching is next performed using the photoresist layer as a mask to remove the portion of the conductive layer 104 exposed thereby. Thus, a plurality of isolated conductive segments 104a is formed. FIG. 6B illustrates a cross section taken along line 6B-6B in FIG. 6A.

Next, the structure illustrated in FIGS. 6A and 6B are processed by the fabrications illustrated in FIGS. 3A-3B, 4A-4B and 5A-5B, thereby forming the structure illustrated in FIGS. 7A and 7B. Thus, a phase change memory device according to this embodiment is substantially fabricated. As shown in FIG. 7A, the dotted area 300b illustrates an area of a memory cell unit and FIG. 7B illustrates a cross section thereof, including a first electrode (the conductive segment 104a) disposed over a substrate (the substrate 102) along a first direction. A first dielectric layer (the dielectric layer 106) is formed over the first electrode. A conductive contact (the conductive contact 108a) is formed in the first dielectric layer, electrically contacting the first electrode, wherein the conductive contact has an L-shaped or reverse L-shaped ( [symbol] ) cross section. A second dielectric layer (the dielectric layer 116) is formed over the first dielectric layer, covering the conductive contact. A phase change layer (the phase change layer 114) is partially formed over the first and the second dielectric layers, electrically contacting the conductive contact. A third dielectric layer is formed over the phase change layer and the first and second dielectric layers, having an opening exposing a portion of the phase change layer. A second electrode layer (the conductive layer 118) is formed over the third dielectric layer, filling the opening and electrically contacting the phase change layer.

The memory cell unit illustrated in the above embodiment is a single-bit memory cell, the first electrode (the conductive segment 104a) therein may electrically connect an active device (not shown) formed over the substrate 102 and provide two different memory statuses through the operation of the second electrode (the conductive layer 118). In addition, a more integrated phase memory device array can be achieved by repeatedly arranging the memory cell unit illustrated in FIGS. 7A and 7B and a simplified process requiring only seven photolithography steps. Thus, a memory cell array of higher cell density and reduced performance variations thereof is obtained, thereby reducing or even preventing the undesired issues of U.S. Pat. No. 6,534,780. Moreover, the conductive contact of an L-shaped or reverse L-shaped ( [symbol] ) cross section in the memory cell functions as a conductive electrode formed between the underlying and overlying electrodes, having a reduced contact area therebetween. Thus a volume occupied in the memory cell is reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase-change memory (PSM) cell, comprising:
a first electrode disposed over a substrate along a first direction;
a first dielectric layer overlying the first electrode;
a conductive contact formed in the first dielectric layer, electrically contacting the first electrode, wherein the conductive contact has a L-shaped or reverse L-shaped ( [symbol] ) cross section;
a second dielectric layer overlying the first dielectric layer, covering the conductive contact;
a phase change layer partially overlying the first and the second dielectric layers, electrically contacting the conductive contact;
a third dielectric layer overlying the phase change layer and the first and second dielectric layers, having an opening exposing a portion of the phase change layer; and
a second electrode layer overlying the third dielectric layer, filling the opening and electrically contacting the phase change layer.

2. The PSM cell as claimed in claim 1, wherein the conductive contact comprises a bottom portion extending along a top surface of the first electrode layer and a sidewall portion extending along and penetrating the first and second dielectric layers, wherein the bottom portion electrically contacts the first electrode and a top end of the sidewall portion electrically contacts the phase change layer.

3. The PSM cell as claimed in claim 1, wherein the phase change layer is embedded in the third dielectric layer and the second electrode comprises a protrusion extending downward into the third dielectric layer to electrically contact the phase change layer.

4. The PSM cell as claimed in claim 1, wherein the phase change layer comprises chalcogenide materials.

5. The PSM cell as claimed in claim 1, wherein the first dielectric layer comprises BPSG, silicon nitride or silicon oxide.

6. The PSM cell as claimed in claim 1, wherein the second and third dielectric layers comprise BPSG, silicon oxide or spin on glass (SOG).

7. The PSM cell as claimed in claim 1, wherein the conductive contact comprises TiN, TaN, TiAlN or TiW.

8. A phase-change memory (PSM) cell, comprising:
a first electrode disposed over a substrate along a first direction;
a first dielectric layer covering the first electrode and the substrate;
a pair of conductive contacts respectively formed in different portions of the first dielectric layer, respectively electrically contacting the first electrode, wherein the conductive contacts have a L-shaped or reverse L-shaped ( [symbol] ) cross section;
a second dielectric layer overlying the first dielectric layer, covering the conductive contacts;
a phase change layer partially overlying the first and the second dielectric layers, electrically contacting one of the conductive contacts;
a third dielectric layer overlying the phase change layer and the first and second dielectric layers, having an opening exposing a portion of the phase change layer; and
a second electrode overlying the third dielectric layer along a second direction and filling the opening, electrically contacting the phase change layer.

9. The PSM cell as claimed in claim 8, wherein the PSM cell comprises two memory bits.

10. The PSM cell as claimed in claim 8, wherein each of the conductive contacts comprise a bottom portion extending along a top surface of the first electrode layer and a sidewall portion extending along and penetrating the first and second dielectric layers, wherein the bottom portion electrically contacts the first electrode and a top end of the sidewall portion electrically contacts the phase change layer.

11. The PSM cell as claimed in claim 8, wherein the phase change layer is embedded in the third dielectric layer and the second electrode comprises a protrusion extending downward in the third electric layer to electrically contact the phase change layer.

12. The PSM cell as claimed in claim 8, wherein the phase change layer comprises a chalcogenide material.

13. The PSM cell as claimed in claim 8, wherein the first dielectric layer comprises BPSG, silicon nitride or silicon oxide.

14. The PSM cell as claimed in claim 8, wherein the second and third dielectric layers comprise BPSG, silicon oxide or spin on glass (SOG).

15. The PSM cell as claimed in claim 8, wherein the conductive contact comprises TiN, TaN, TiAlN or TiW.

16. A method for fabricating a phase-change memory (PSM) cell, comprising:
forming a first electrode over a substrate, wherein the first electrode extends along a first direction and partially covers the substrate;
forming a first dielectric layer over the substrate, covering the first electrode and the substrate;
forming a first opening in the first dielectric layer, exposing a portion of the first electrode;
forming a pair of conductive contacts of L-shaped or reverse L-shaped ( [symbol] ) cross section respectively on both sides of the first opening, the conductive contacts contact the first electrode and a sidewall of the first dielectric layer exposed by the first opening, respectively;
filling the first opening with a second dielectric layer, wherein the second dielectric layer covers the conductive contacts;
forming a pair of phase change layers, each of the phase change layers partially overlying the first and second dielectric layers, electrically contacting the conductive contact;
forming a third dielectric layer over the phase change layers and the first and second dielectric layers;
forming a pair of second openings in the third dielectric layer, respectively exposing a portion of each of the phase change layers; and
forming a second electrode over the third dielectric layer, extending along a second direction and filling the second openings, respectively electrically contacting the phase change layers, wherein the second direction is different to that of the first direction.

17. The method as claimed in claim 16, wherein forming a pair of conductive contacts of L-shaped or reverse L-shaped ( [symbol] ) cross section on both sides of the first opening comprising:
forming a conductive layer over the first dielectric layer, covering the first dielectric layer and the first electrode in the first opening;
forming a photoresist layer, covering the conductive layer and the first opening;
forming a third opening in the photoresist layer, wherein the third opening partially exposes the conductive layer formed in the first opening;
etching the conductive layer exposed by the third opening, using the photoresist layer as a mask; and
removing the resist layer, leaving the pair of conductive contacts of L-shaped or reverse L-shaped ( [symbol] ) cross sections in the first opening.

18. The method as claimed in claim 17, wherein the first electrode underlying the conductive layer exposed by the third opening is simultaneously removed during formation of the conductive contacts of L-shaped or reverse L-shaped ( [symbol] ) cross sections in the first opening, such that the first electrode is divided into a first electrode segment and a second electrode segment.

19. The method as claimed in claim 16, wherein the PSM cell comprises a dual-bit unit.

20. The method as claimed in claim 18, wherein the PSM cell comprise two isolated single-bit units.

21. The method as claimed in claim 16, wherein each of the conductive contacts of L-shaped or reverse L-shaped ( [symbol] ) cross sections comprise a bottom portion extending along a top surface of the first electrode layer and a sidewall portion extending along the first and second dielectric layers and penetrating thereof, wherein the bottom portion electrically contacts the first electrode and a top end of the sidewall portion electrically contacts the phase change layer.

22. The method as claimed in claim 16, wherein the phase change layers comprise chalcogenide materials.

23. The method as claimed in claim 16, wherein the first dielectric layer comprises BPSG, silicon nitride or silicon oxide.

24. The method as claimed in claim 16, wherein the second and third dielectric layers comprise BPSG, silicon oxide or spin on glass (SOG).

25. The method as claimed in claim 16, wherein the conductive contact comprises TiN, TaN, TiAlN or TiW.
